(19) United States
(12) Patent Application Publication
(10) Pub. No.: US 2025/0311390 A1
(43) Pub. Date: Oct. 2, 2025

(54) Diodes with False Collectors Sandwiching and Tied to Anode

(71) Applicant: Texas Instruments Incorporated, Dallas, TX (US)

(72) Inventors: Archana Venugopal, Mountain View, CA (US); Alexei Sadovnikov, Sunnyvale, CA (US)

(21) Appl. No.: 18/620,875

(22) Filed: Mar. 28, 2024

(51) Int. Cl. H01L 29/78; H01L 21/265; H01L 29/06; H01L 29/66

(52) U.S. Cl. CPC H10D 84/154; H01L 21/26513; H10D 30/0281; H10D 30/655; H10D 62/107; H10D 62/109

(57) ABSTRACT

The present disclosure introduces semiconductor devices that include a first doped region having a first dopant type, a second doped region having a second dopant type different from the first dopant type, and third and fourth doped regions. The third and fourth doped regions have the first dopant type, contact corresponding opposite sides of the second doped region, and are electrically connected to the second doped region. The present disclosure also introduces diode implementations of such semiconductor devices, as well as methods of manufacturing such semiconductor devices.

### BACKGROUND OF THE DISCLOSURE

Integrated circuit (IC) devices often include transistors and diodes, among other semiconductor-based components. Such components are often designed for specific voltage applications, such as low-voltage components (i.e., 5 volts (V) or less), high-voltage components (i.e., 1 kilovolt (kV) or more), and medium-voltage components (i.e., between 5 V and 1 kV). However, within one or more of such voltage ranges, standalone diodes may not exist, such that IC designers are forced to use one or more metal-oxide semiconductor (MOS) devices (e.g., laterally-diffused MOS (LDMOS) devices or double-diffused MOS (DMOS) devices, among others) individually or collectively configured as a diode. However, such MOS devices are optimized for breakdown voltage and on-state resistance for their normal operations (e.g., when configured as non-diode devices), which is not ideal when they are utilized as diodes. Configuring such MOS devices as a diode is also more expensive and requires more real estate than a standalone diode.

### SUMMARY OF THE DISCLOSURE

This summary is provided to introduce a selection of concepts that are further described below in the detailed description. This summary is not intended to identify indispensable features of the claimed subject matter, nor is it intended for use as an aid in limiting the scope of the claimed subject matter.

The present disclosure introduces a semiconductor device that includes a first doped region having a first dopant type, a second doped region having a second dopant type different from the first dopant type, and third and fourth doped regions. The third and fourth doped regions have the first dopant type, contact corresponding opposite sides of the second doped region, and are electrically connected to the second doped region.

The present disclosure also introduces a diode formed in a semiconductor substrate, the diode including a cathode having an n-type region, an anode laterally surrounding the cathode and having a p-type region, a first false collector laterally surrounding the cathode and contacting an inner boundary of the anode, a second false collector laterally surrounding the anode and contacting an outer boundary of the anode, and a conductive layer over and electrically connecting the anode and the first and second false collectors.

The present disclosure also introduces a method of forming a semiconductor device, including implanting a first type dopant in a semiconductor substrate to form a first doped region and implanting a second type dopant in the semiconductor substrate to form a second doped region. The second type dopant is different from the first type dopant. The method also includes implanting the first type dopant in the semiconductor substrate to form third and fourth doped regions that contact corresponding opposite sides of the second doped region. A conductive layer is formed over and electrically connecting the second, third, and fourth doped regions.

These and additional aspects of the present disclosure are set forth in the description that follows, and/or may be learned by a person having ordinary skill in the art by reading the material herein and/or practicing the principles described herein. At least some aspects of the present disclosure may be achieved via means recited in the attached claims.

### BRIEF DESCRIPTION OF THE DRAWINGS

The present disclosure is understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a circuit diagram of at least a portion of an example implementation of a transceiver circuit according to one or more aspects of the present disclosure.

FIG. 2 is a sectional view of at least a portion of an example implementation of a standalone diode according to one or more aspects of the present disclosure.

FIG. 3 is a plan view of the standalone diode shown in FIG. 2.

FIG. 4 is a flow-chart diagram of at least a portion of an example implementation of a method of manufacturing a standalone diode according to one or more aspects of the present disclosure.

### DETAILED DESCRIPTION

It is to be understood that the following disclosure provides many different examples for different features of various implementations. Specific examples of components and arrangements are described below to simplify the present disclosure. These are, of course, merely examples and are not intended to be limiting. In addition, the present disclosure may repeat reference numerals and/or letters in the various examples. This repetition is for simplicity and clarity, and does not in itself dictate a relationship between the various examples and/or configurations discussed. Moreover, the formation of a first feature over or on a second feature in the description that follows may include examples in which the first and second features are formed in direct contact, and may also include examples in which additional features may be formed interposing the first and second features, such that the first and second features may not be in direct contact.

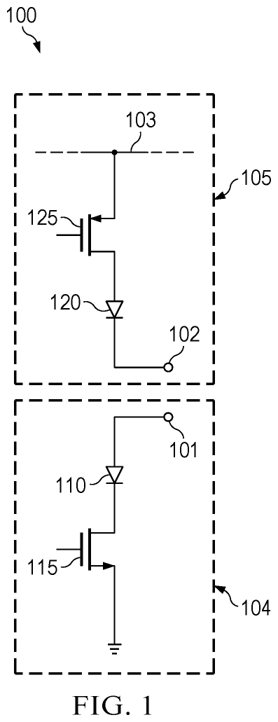

FIG. 1 is a circuit diagram of at least a portion of an example implementation of a transceiver circuit 100 according to one or more aspects of the present disclosure. The transceiver circuit 100 includes a first node 101 (e.g., an input node) connected to the anode of a diode 110. The cathode of the diode 110 is connected to the drain of an n-channel MOS (NMOS) device 115. The source of the NMOS device 115 is connected to ground. The transceiver circuit 100 also includes a second node 102 (e.g., an output node) connected to the cathode of a diode 120. The anode of the diode 120 is connected to the drain of a p-channel MOS (PMOS) device 125. The source of the PMOS device 125 is connected to a voltage (e.g., VDD) 103.

The example transceiver circuit 100 is configured as a transceiver, including a receiver portion 104 that includes the input node 101, the diode 110, and the NMOS device 115, as well as a transmitter portion 105 that includes the output node 102, the diode 120, and the PMOS device 125. During normal operation, for example, the forward-biased nature of the diode 120 permits a signal from the PMOS device 125 to pass to the output node 102. When the output node 102 somehow experiences an excess voltage (e.g., about 60 V), the diode 120 will block that signal from being transmitted to the PMOS device 125.

Similarly, the diode 110 under normal operation permits an input signal to flow from the input node 101 to the NMOS device 115. But if somehow the input signal reverses direction, the diode 110 will block that signal from being transmitted to the NMOS device 115.

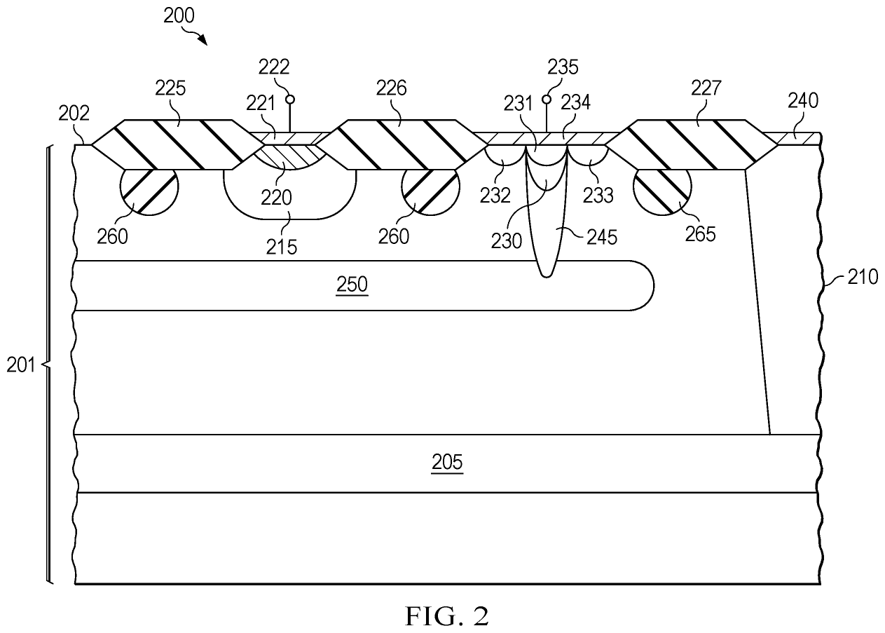

FIG. 2 is a sectional view of at least a portion of an example implementation of a semiconductor device 200 according to one or more aspects of the present disclosure. The semiconductor device 200 is formed in/on a semiconductor substrate 201, such as silicon or other semiconductive materials. The semiconductor device 200 includes a first doped region 215, a second doped region 230, a third doped region 232, and a fourth doped region 233. The first doped region 215 has a first dopant type, whereas the second doped region 230 has a second dopant type different from the first dopant type.

The third and fourth doped regions 232, 233 have the first dopant type, although a concentration of the first dopant type in the third and fourth doped regions may be higher than a concentration of the first dopant type in the first doped region. The third and fourth doped regions 232, 233 contact corresponding opposite sides of the second doped region 230. The third and fourth doped regions 232, 233 may be electrically connected to the second doped region 230. For example, a portion 234 of a silicide (and/or other conductive material) layer may be formed on the second, third, and fourth doped regions 230, 232, 233 such that the second, third, and fourth doped regions 230, 232, 233 are electrically shorted.

Among other applications within the scope of the present disclosure, the semiconductor device 200 may be a standalone diode, such as may be utilized for either or both of the diodes 110, 120 shown in FIG. 1. In such implementations, among others within the scope of the present disclosure, the first doped region 215 forms a cathode of the diode, the second doped region 230 forms an anode of the diode, and the third and fourth doped regions 232, 233 form false collectors of the diode.

The semiconductor device 200 may further comprise a fifth doped region 260 having the second dopant type and laterally interposing the first and second doped regions 215, 230. Alternatively, or in addition thereto, the semiconductor device 200 may further comprise a sixth doped region 265 having the second dopant type and laterally interposing the second doped region 230 and a deep well 210 extending vertically to a buried layer 205. The deep well 210 and the buried layer 205 may each have the first dopant type.

The following description pertains to an example implementation in which the semiconductor device 200 is a standalone diode according to one or more aspects of the present disclosure, wherein the semiconductor substrate 201 is a p-doped silicon substrate, the first dopant type is an n-type dopant, and the second dopant type is a p-type dopant. For example, the buried layer 205 may be an n-doped buried layer (NBL) 205 extending horizontally across the substrate 201. The deep well 210 may be an n-doped deep well (DEEPN) 210 forming a ring extending horizontally around the diode and vertically from a surface 202 of the substrate 201 to the NBL 205. Thus, the NBL 205 and the DEEPN 210 may collectively form an n-doped tank surrounding the diode.

The first doped region 215 may be an n-doped well (N_{well}) 215 forming the cathode of the diode. An n+ doped shallow region 220 in the N_{well} 215, as well as another portion 221 of the silicide layer on the n+ doped shallow region 220, may collectively form an n+cathode contact 222 between opposing isolation structures 225, 226. The isolation structures 225, 226, as well as an additional isolation structure 227, may be local oxidation of silicon (LOCOS), shallow trench isolation (STI), and/or other electrically insulating features.

In the above example, the second doped region 230 may be a p-doped well (Pwell) 230 forming the anode of the diode 200, whereas the third doped region is 232 may be an inner n+ doped false collector 232 and the fourth doped region 233 may be an outer n+ doped false collector 233. A p+ doped shallow region 231 in the Pwell 230 and sandwiched between the inner and outer n+false collectors 232, 233, as well as the silicide layer portion 234 connecting the p+ doped shallow region 231 to the false collectors 232, 233, may collectively form an anode contact 235 between the isolation structures 226, 227. Another portion 240 of the silicide layer may be formed over the DEEPN 210 and perhaps a portion of the isolation structure 227.

The Pwell 230 may be located in a p-doped deep well (Dwell) 245 extending down into the substrate 201. In some examples, an additional buried layer 250 may horizontally extend within the substrate 201 at a distance above the NBL 205. The additional buried layer 250 may form a reduced surface field (RESURF) region, such as a p-doped RESURF region (e.g., a PRSRF region). The Dwell 245 may extend vertically to contact the second buried layer 250.

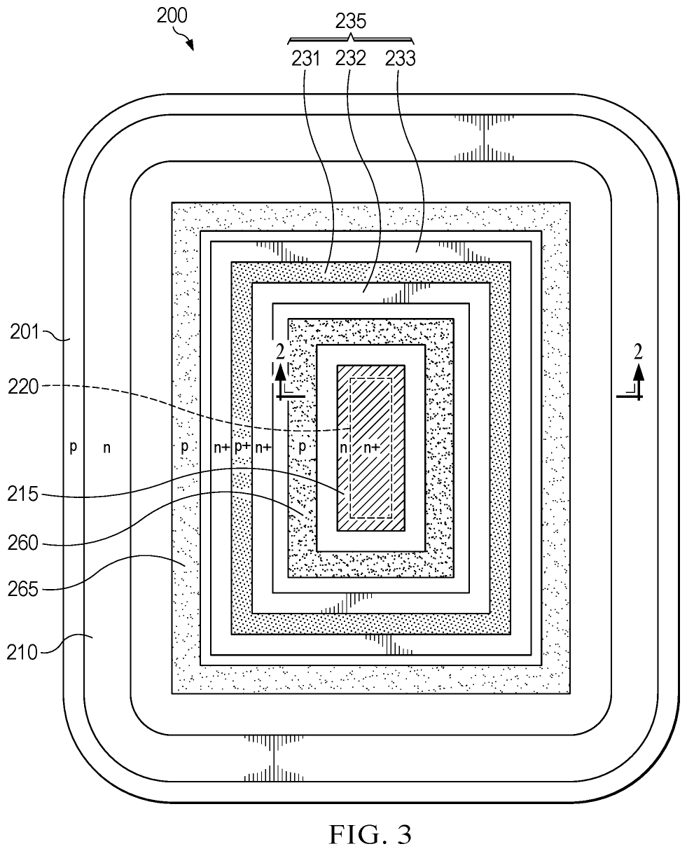

The fifth doped region 260 may be a p-doped inner guard ring 260 extending in a ring shape (e.g., see FIG. 3) around the cathode. The sixth doped region 265 may be a p-doped outer guard ring 265 extending in a ring shape (e.g., see FIG. 3) around the anode. The diode may include one or both of the guard rings 260, 265.

FIG. 3 is a plan view of the semiconductor device 200 that is partially shown in FIG. 2, as indicated in FIG. 3 by section-cut lines 2. As shown in FIG. 3, the n+ doped shallow region 220 may be a rectangular or otherwise elongated region, although other shapes are also within the scope of the present disclosure. The N_{well} 215 includes the n+ doped shallow region 220. The inner guard ring 260 (if extant) laterally surrounds but is radially spaced from the Nwell 215. The anode 235 (including the p+ doped shallow region 231 radially sandwiched between the false collectors 232, 233) laterally surrounds but is radially spaced from the inner guard ring 260 (if extant) and/or the Nwell 215. The outer guard ring 265 (if extant) laterally surrounds (and may be radially spaced from) the anode 235 within an inner boundary of the DEEPN 210. The DEEPN 210 laterally surrounds the diode and is radially spaced from the outer guard ring 265 (if extant) and/or the anode 235.

If the diode depicted in FIGS. 2 and 3 is under a forward bias, electrons received at the anode will generally travel down to the NBL 205, but some of the electrons may travel laterally and be collected by the DEEPN 210. In some examples, the n-type region 233 may reduce this collecting efficiency by serving as a so-called false collector of the n-p-n bipolar transistor. For example, the n-p-n bipolar transistor may be formed by the cathode n-type region 215, the lightly doped p-type epi (the region vertically interposing the inner guard ring 260 and the buried layer 250), and the n-type region 233. This n-p-n bipolar transistor will be shorter than the n-p-n bipolar transistor formed by the cathode n-type region 215 and the DEEPN 210 (with the p-type epi therebetween), so that at least some of the injected electrons may be collected by the false collector. The false collector formed by the n-type region 233 (the outer n+ doped false collector 233) may be a false collector for the n-type cathode 220 being forward biased, and the other false collector formed by the n-type region 232 (the inner n+ doped false collector 232) may be a false collector for the DEEPN 210 being forward biased (such that electrons injected from the DEEPN 210 are at least partially collected by the n-type region 232).

The guard rings 260, 265 may be included to mitigate (e.g., reduce, suppress, cut) punch-through under the respective isolation structures 226, 227. For example, if the DEEPN 210 is reverse biased, the lightly doped p-epi underneath the isolation structure 227 and around the DEEPN 210 may be depleted between the n-type region 233 and the DEEPN 210 such that the depletion region of the DEEPN 210 may expand to the left and ultimately contact the n-type region 233. The outer guard ring 265 may be included in order to stop such propagation of the depletion region. The inner guard ring 260 may similarly be included to stop similar propagation of the depletion region between the cathode N_{well} 215 and the n-type region 232.

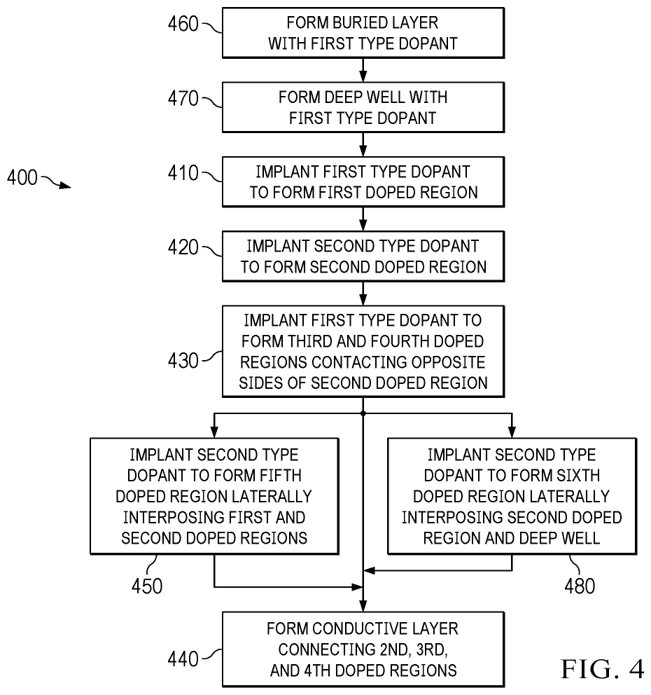

FIG. 4 is a flow-chart diagram of at least a portion of an example implementation of a method 400 of forming a semiconductor device, such as the diode 200 shown in FIGS. 2 and 3, according to one or more aspects of the present disclosure. The method 400 includes implanting a first type dopant to form a first doped region (box 410). For example, implanting the first type dopant may result in an n-type concentration ranging between 1e¹⁶ (1×10¹⁶/cm³) and 1e¹⁸ (1×10¹⁸/cm³). Implanting the first type dopant may form a cathode of the semiconductor device, such as the N_{well} 215 shown in FIGS. 2 and 3.

The method 400 also includes implanting a second type dopant to form a second doped region (box 420). For example, implanting the second type dopant may result in a p-type concentration ranging between 1e¹⁶ and 1e¹⁸. Implanting the second type dopant may form at least a portion of an anode of the semiconductor device, such as the Pwell 230 shown in FIGS. 2 and 3.

The first type dopant is also implanted to form third and fourth doped regions contacting opposite sides of the second doped region (box 430). Implanting the first type dopant to form third and fourth doped regions may result in an n-type concentration that is higher than the concentration resulting from implanting the first type dopant to form the first doped region (e.g., N_{well} 215). For example, the resulting concentration of the first type dopant in the third and fourth doped regions may range between 1e¹⁸ and 1e²⁰ (1×10²⁰/cm³). Implanting the first type dopant to form third and fourth doped regions may form false collectors on opposing sides of the anode of the semiconductor device, such as the n-doped regions 232, 233 shown in FIGS. 2 and 3.

A conductive layer is subsequently formed to electrically connect the second, third, and fourth doped regions (box 440). For example, forming the conductive layer may comprise forming a silicide and/or other conductive material via one or more deposition processes.

The method 400 may also comprise forming a buried layer with the first type dopant (box 460). Such a buried layer may be formed prior to the above-described implanting steps (boxes 410-430). For example, forming the buried layer may comprise implanting the first type dopant resulting in an n-type concentration ranging between 1e¹⁴ (1×10¹⁴/cm³) and 1e¹⁷ (1×10¹⁷/cm³). Forming the buried layer may result in an n-doped buried layer (e.g., NBL), such as the buried layer 205 shown in FIG. 2.

The method 400 may also comprise forming a deep well with the first type dopant (box 470) after forming the buried layer (e.g., buried layer 205, NBL). The deep well may be formed prior to the above-described implanting steps (boxes 410-430). For example, forming the deep well may comprise implanting the first type dopant resulting in an n-type concentration ranging between 1e¹⁷ and 1e²⁰. The deep well may extend vertically from a surface of the semiconductor substrate to a depth to reach the previously formed buried layer (e.g., the buried layer 205). The DEEPN 210 shown in FIGS. 2 and 3 is an example of the deep well.

The method 400 may also comprise forming a buried layer including the second type dopant. The buried layer including the second type dopant may also be formed prior to the above-described implanting steps (boxes 410-430). For example, forming the buried layer including the second type dopant may comprise implanting the second type dopant resulting in a p-type concentration ranging between 1e¹⁴ (1×10¹⁴/cm³) and 1e¹⁷ (1×10¹⁷/cm³). Forming the buried layer including the second type dopant may result in a PRSRF or other RESURF region, such as the buried layer 250 shown in FIG. 2.

The method 400 may also comprise implanting the second type dopant to form a fifth doped region laterally interposing the first and second doped regions (box 450). Implanting the second type dopant may result in a p-type concentration that is lower than the concentration resulting from implanting the second type dopant to form the second doped region. For example, the resulting concentration of the second type dopant in the fifth doped region may range between 1e¹⁶ and 1e¹⁸. Implanting the second type dopant to form a fifth doped region may form a propagation guard between the cathode and anode of the semiconductor device, such as the guard ring 260 shown in FIGS. 2 and 3.

The method 400 may also comprise, whether instead of or in addition to implanting the second type dopant to form a fifth doped region, implanting the second type dopant to form a sixth doped region laterally interposing the second doped region and the deep well (box 480). Implanting the second type dopant to form a sixth doped region may result in a p-type concentration that is lower than the concentration resulting from implanting the second type dopant to form the second doped region (box 420). For example, the resulting concentration of the second type dopant in the sixth doped region may range between 1e¹⁶ and 1e¹⁸. Implanting the second type dopant to form the sixth doped region may form a propagation guard between the anode and deep well of the semiconductor device, such as the guard ring 265 shown in FIGS. 2 and 3.

In view of the entirety of the present disclosure, including the figures and the claims, it is readily apparent that the present disclosure introduces a semiconductor device comprising: a first doped region having a first dopant type; a second doped region having a second dopant type different from the first dopant type; and third and fourth doped regions. The third and fourth doped regions have the first dopant type, contact corresponding opposite sides of the second doped region, and are electrically connected to the second doped region.

The semiconductor device may operate as a diode, the first doped region may form a cathode of the diode, the second doped region may form an anode of the diode, and the third and fourth doped regions may form false collectors of the diode.

The semiconductor device may comprise one or both of: a fifth doped region having the second dopant type and laterally interposing the first and second doped regions; and a sixth doped region having the second dopant type and laterally interposing the second doped region and a deep well extending vertically to a buried layer, the deep well and the buried layer each having the first dopant type. In such implementations, the second doped region may laterally surround the first doped region, the third doped region may laterally surround the first doped region within an inner boundary of the second doped region, the fourth doped region may laterally surround the second doped region, the fifth doped region (if extant) may laterally surround the first doped region within an inner boundary of the third doped region, the deep well may laterally surround the fourth doped region, and the sixth doped region (if extant) may laterally surround the fourth doped region within an inner boundary of the deep well.

The semiconductor device may be formed in a p-type silicon substrate, the first dopant type may be an n-type dopant, and the second dopant type may be a p-type dopant. In such implementations, the semiconductor device may comprise a well having the second dopant type. The well may extend from the second doped region toward a buried layer having the first dopant type. The well may extend from the second doped region to a buried layer having the second dopant type. A concentration of the n-type dopant in the third and fourth doped regions may be higher than a concentration of the n-type dopant in the first doped region.

The second, third, and fourth doped regions may be electrically connected by an overlying layer of silicide.

The first doped region may comprise a fifth doped region having the first dopant type. A concentration of the first dopant type in the fifth doped region may be higher than a concentration of the first dopant type in the first doped region.

The present disclosure also introduces a diode formed in a semiconductor substrate, the diode comprising: a cathode comprising an n-type region; an anode laterally surrounding the cathode and comprising a p-type region; a first false collector laterally surrounding the cathode and contacting an inner boundary of the anode; a second false collector laterally surrounding the anode and contacting an outer boundary of the anode; and a conductive layer over and electrically connecting the anode and the first and second false collectors.

Both of the first and second false collectors may be n-type. In such implementations, the p-type region may be a first p-type region and the diode may further comprise one or both of: an inner guard ring laterally surrounding the cathode within an inner boundary of the first false collector, the inner guard ring including a second p-type doped region; and an outer guard ring laterally surrounding the second false collector within an inner boundary of a deep well extending vertically to a buried layer. The outer guard ring may comprise a third p-type doped region, the deep well may laterally surround the outer guard ring, and the deep well and the buried layer may each be n-type. A concentration of the n-type dopant in the first and second false collectors may be higher than a concentration of the n-type dopant in the n-type region.

The present disclosure also introduces a method of forming a semiconductor device, comprising: implanting a first type dopant in a semiconductor substrate to form a first doped region; implanting a second type dopant in the semiconductor substrate to form a second doped region, the second type dopant being different from the first type dopant; implanting the first type dopant in the semiconductor substrate to form third and fourth doped regions that contact corresponding opposite sides of the second doped region; and forming a conductive layer over and electrically connecting the second, third, and fourth doped regions.

The method may comprise implanting the second type dopant in the semiconductor substrate to form a fifth doped region laterally interposing the first and second doped regions.

The method may comprise, before forming the first, second, third, and fourth doped regions: forming a buried layer with the first type dopant in the semiconductor substrate; and forming a deep well with the first type dopant, wherein the deep well extends from a surface of the semiconductor substrate to the buried layer. In such implementations, the method may further comprise implanting the second type dopant in the semiconductor substrate to form another doped region laterally interposing the second doped region and the deep well.

The method may comprise: (A) implanting the second type dopant in the semiconductor substrate to form a fifth doped region laterally interposing the first and second doped regions; (B) before forming the first, second, third, and fourth doped regions: forming a buried layer with the first type dopant in the semiconductor substrate; and forming a deep well with the first type dopant, the deep well extending from a surface of the semiconductor substrate to the buried layer; and (C) implanting the second type dopant in the semiconductor substrate to form a sixth doped region laterally interposing the second doped region and the deep well. In such implementations: implanting the first type dopant to form the first doped region may comprise implanting the first type dopant to a first concentration; implanting the first type dopant to form the third and fourth doped regions may comprise implanting the first type dopant to a second concentration that is higher than the first concentration; implanting the second type dopant to form the second doped region may comprise implanting the second type dopant to a third concentration; and implanting the second type dopant to form the fifth and sixth doped regions may comprise implanting the second type dopant to a fourth concentration that is lower than the third concentration.

The foregoing outlines features of several examples so that a person having ordinary skill in the art may better understand the aspects of the present disclosure. A person having ordinary skill in the art should appreciate that they may readily use the present disclosure as a basis for designing or modifying other processes and structures for carrying out the same functions and/or achieving the same benefits of the examples introduced herein. A person having ordinary skill in the art should also realize that such equivalent constructions do not depart from the spirit and scope of the present disclosure, and that they may make various changes, substitutions and alterations herein without departing from the spirit and scope of the present disclosure.

The Abstract at the end of this disclosure is provided to comply with 37 C.F.R. § 1.72 (b) to permit the reader to quickly ascertain the nature of the technical disclosure. It is submitted with the understanding that it will not be used to interpret or limit the scope or meaning of the claims.

What is claimed is:

1. A semiconductor device, comprising:
a first doped region having a first dopant type;
a second doped region having a second dopant type different from the first dopant type; and
third and fourth doped regions that:
have the first dopant type;
contact corresponding opposite sides of the second doped region; and
are electrically connected to the second doped region.

2. The semiconductor device of claim 1 wherein:
the semiconductor device operates as a diode;
the first doped region forms a cathode of the diode;
the second doped region forms an anode of the diode; and
the third and fourth doped regions form false collectors of the diode.

3. The semiconductor device of claim 1 further comprising at least one of:
a fifth doped region having the second dopant type and laterally interposing the first and second doped regions; and
a sixth doped region having the second dopant type and laterally interposing the second doped region and a deep well extending vertically to a buried layer, wherein the deep well and the buried layer each have the first dopant type.

4. The semiconductor device of claim 3 comprising both of the fifth and sixth doped regions.

5. The semiconductor device of claim 3 wherein:
the second doped region laterally surrounds the first doped region;
the third doped region laterally surrounds the first doped region within an inner boundary of the second doped region;
the fourth doped region laterally surrounds the second doped region;
the fifth doped region, if extant, laterally surrounds the first doped region within an inner boundary of the third doped region;
the deep well laterally surrounds the fourth doped region; and
the sixth doped region, if extant, laterally surrounds the fourth doped region within an inner boundary of the deep well.

6. The semiconductor device of claim 1 wherein:
the semiconductor device is formed in a p-type silicon substrate;
the first dopant type is an n-type dopant; and
the second dopant type is a p-type dopant.

7. The semiconductor device of claim 6 wherein a concentration of the n-type dopant in the third and fourth doped regions is higher than a concentration of the n-type dopant in the first doped region.

8. The semiconductor device of claim 6 further comprising:
a buried layer having the first dopant type; and
a well having the second dopant type and extending from the second doped region toward the buried layer.

9. The semiconductor device of claim 6 further comprising:
a buried layer having the second dopant type; and
a well having the second dopant type and extending from the second doped region to the buried layer.

10. The semiconductor device of claim 1 wherein the second, third, and fourth doped regions are electrically connected by an overlying layer of silicide.

11. The semiconductor device of claim 1 wherein the first doped region comprises a fifth doped region having the first dopant type, wherein a concentration of the first dopant type in the fifth doped region is higher than a concentration of the first dopant type in the first doped region.

12. A diode formed in a semiconductor substrate, the diode comprising:
a cathode comprising an n-type region;
an anode laterally surrounding the cathode and comprising a p-type region;
a first false collector laterally surrounding the cathode and contacting an inner boundary of the anode;
a second false collector laterally surrounding the anode and contacting an outer boundary of the anode; and
a conductive layer over and electrically connecting the anode and the first and second false collectors.

13. The diode of claim 12 wherein both of the first and second false collectors are n-type.

14. The diode of claim 13 wherein a concentration of the n-type dopant in the first and second false collectors is higher than a concentration of the n-type dopant in the n-type region.

15. The diode of claim 12 wherein:
the p-type region is a first p-type region; and
the diode further comprises at least one of:
an inner guard ring laterally surrounding the cathode within an inner boundary of the first false collector, wherein the inner guard ring includes a second p-type doped region; and
an outer guard ring laterally surrounding the second false collector within an inner boundary of a deep well extending vertically to a buried layer.

16. The diode of claim 15 wherein:
the outer guard ring comprises a third p-type doped region;
the deep well laterally surrounds the outer guard ring; and
the deep well and the buried layer are each n-type.

17. The diode of claim 15 comprising both of the inner and outer guard rings.

18. A method of forming a semiconductor device, comprising:
implanting a first type dopant in a semiconductor substrate to form a first doped region;
implanting a second type dopant in the semiconductor substrate to form a second doped region, wherein the second type dopant is different from the first type dopant;
implanting the first type dopant in the semiconductor substrate to form third and fourth doped regions that contact corresponding opposite sides of the second doped region; and
forming a conductive layer over and electrically connecting the second, third, and fourth doped regions.

19. The method of claim 18 further comprising implanting the second type dopant in the semiconductor substrate to form a fifth doped region laterally interposing the first and second doped regions.

20. The method of claim 18 further comprising:
before forming the first, second, third, and fourth doped regions:
forming a buried layer with the first type dopant in the semiconductor substrate; and
forming a deep well with the first type dopant, wherein the deep well extends from a surface of the semiconductor substrate to the buried layer; and
implanting the second type dopant in the semiconductor substrate to form another doped region laterally interposing the second doped region and the deep well.

21. The method of claim 18 further comprising:
implanting the second type dopant in the semiconductor substrate to form a fifth doped region laterally interposing the first and second doped regions;
before forming the first, second, third, and fourth doped regions:
forming a buried layer with the first type dopant in the semiconductor substrate; and
forming a deep well with the first type dopant, wherein the deep well extends from a surface of the semiconductor substrate to the buried layer; and
implanting the second type dopant in the semiconductor substrate to form a sixth doped region laterally interposing the second doped region and the deep well.

22. The method of claim 21 wherein:
implanting the first type dopant to form the first doped region comprises implanting the first type dopant to a first concentration;
implanting the first type dopant to form the third and fourth doped regions comprises implanting the first type dopant to a second concentration that is higher than the first concentration;
implanting the second type dopant to form the second doped region comprises implanting the second type dopant to a third concentration; and
implanting the second type dopant to form the fifth and sixth doped regions comprises implanting the second type dopant to a fourth concentration that is lower than the third concentration.
